(19) United States
(12) Patent Application Publication
(10) Pub. No.: US 2006/0065889 A1
(43) Pub. Date: Mar. 30, 2006

(54) Compositions for making organic thin films used in organic electronic devices

(76) Inventor: Pierre-Marc Allemand, San Jose, CA (US)

Correspondence Address: EPPING, HERMANN, FISCHER, Ridlerstrasse 55, Munich, 80339, DE

(21) Appl. No.: 10/957,142

(22) Filed: Sep. 30, 2004

(51) Int. Cl. H01L 51/50; H01B 1/12; H05B 33/12

(52) U.S. Cl. 257/40; 252/500; 257/E51.029; 428/690; 428/917; 313/504; 313/506; 427/66

(57) ABSTRACT

An organic electronic layer is formed using a monomer dissolved in a solvent such as formic acid. The solution is oxidized with the aid of an oxidizing agent, chosen such that there are no ionic byproducts resulting therefrom. Additives such as polyacids, acids, salts and electrolytes may be added to the solution.

### BACKGROUND

1. Field of the Invention

This invention relates generally to the art of thin film device processing and fabrication. More specifically, the invention relates to the fabrication of Organic Light Emitting Diode devices and displays.

2. Related Art

Display and lighting systems based on LEDs (Light Emitting Diodes) have a variety of applications. Such display and lighting systems are designed by arranging a plurality of photo-electronic elements (“elements”) such as arrays of individual LEDs. LEDs that are based upon semiconductor technology have traditionally used inorganic materials, but recently, the organic LED (“OLED”) has come into vogue for certain lighting and display applications. Examples of other elements/devices using organic materials include organic solar cells, organic transistors, organic detectors, biochips, and organic lasers.

An OLED is typically comprised of two or more thin at least partially conducting organic layers (e.g., a buffer layer) which transports holes (or electrons) and an emissive layer (EL) which emits light upon hole-electron recombination therein) which are sandwiched between two electrodes, an anode and a cathode. Under an applied potential, the anode injects holes into the ABL which then transports them to the EL, while the cathode injects electrons directly to the EL. The injected holes and electrons each migrate toward the oppositely charged electrode and recombine to form an exciton in the EL. The exciton relaxes to a lower energy state by emission of radiation i.e. light. Typically, polymer-based OLED devices have been fabricated by using ABL materials which are based on doped conducting polymers such as PEDOT (polyethylenedioxythiophene) or PANI (polyaniline). PEDOT is often mixed with an acid such as PSS (polystyrenesulfonic acid). One of the most commonly used ABL materials is Baytron P VP CH8000, available from HC Starck Corporation. Baytron P VP CH8000 has a PEDOT:PSS weight ratio of 1:20, and a resistivity of around 100 kOhm-cm. Baytron P VP CH8000 is appropriate for applications such as passive matrix displays which do not require further patterning/processing and provides good photopic efficiency and reasonably low operating voltage requirements. However, with very few exceptions, these device structures do not exhibit desirable lifetimes. One problem with ABL materials such as Baytron CH8000 is that the high PSS content necessary to increase the resistivity required for passive matrix displays is believed to induce bad lifetime. Another problem is that the manufacturing of CH8000 involves several cumbersome steps, such as polymerization, blending, deionization and filtration. Another problem is that since CH8000 is a suspension in water, its surface tension is very high, and surfactant additives are required to process the solution.

It would be desirable to fabricate an ABL with better lifetimes and with less burdensome processing requirements.

### BRIEF DESCRIPTION OF THE DRAWINGS

FIG. 1 illustrates a process flow for fabricating an ABL according to at least one embodiment of the invention.

FIG. 2 shows a cross-sectional view of an embodiment of an OLED device 405 according to at least one embodiment of the invention.

FIG. 3(A) illustrates current-voltage curves for various embodiments of the invention.

FIG. 3(B) and FIG. 3(C) illustrates luminous efficiency for the same four devices as FIG. 3(A).

FIG. 4 illustrates normalized lifetime data for each of the four above-mentioned devices when driven under multiplexed (MUX) conditions.

FIG. 5 illustrates un-normalized lifetime data for each of the four above-mentioned devices when driven under DC conditions.

Other monomers that can be used in accordance with various embodiments of the invention include 3,4-dimethoxythiophene, 3-methoxythiophene, isothianaphthene and its derivatives, and pyrrole and its derivatives.

### DETAILED DESCRIPTION OF THE INVENTION

In describing the various embodiments of the invention, the terms “mixture” and “solution” are intended to have an identical meaning. They refer to a combination or blending of compounds, liquid, solid and gaseous which chemically react and/or physically blended together.

What is disclosed is an ABL formulation that yields better device lifetimes and makes device processing less burdensome. In one embodiment of the invention, a monomer is dissolved in a solvent (e.g. formic acid). One or more additives such as polyacids, acids, and salts can also be incorporated into the solution. Then, the solution is oxidized over a period of time with the assistance of oxidizing agents. For instance, in some embodiments of the invention, mixtures of EDOT (3,4-ethylenedioxythiophene) monomer is dissolved in concentrated formic acid. The solution turned bright blue when left standing for a period of time. This was due to oxidization accelerated by the addition of oxidizing agents such as small amounts of hydrogen peroxide. In accordance with the invention, the oxidizing agents are selected so as not to generate ionic by-products. Otherwise, the ionic by-products would need to be removed by deionization steps to prevent device performance problems. Various polyacids could be added to these solutions. These solutions can be used without any further purification or deionization steps which would ordinarily be needed if they were to be used as ABL materials in OLED devices. Because the surface tension of the as-prepared mixtures was quite low (around 37 dyne/cm), no additional surfactants were needed for its processing. The current-voltage characteristics and lifetimes were good, and the initial large decays in luminance observed using conventional ABL materials was not as prominent. In addition, the ABL when fabricated using materials in accordance with the invention was found to be easier to remove after baking when compared with conventionally used materials. Also, the in-plane resistivity of the ABLs fabricated using these materials were found to be very high, and are therefore quite suitable for passive matrix display applications.

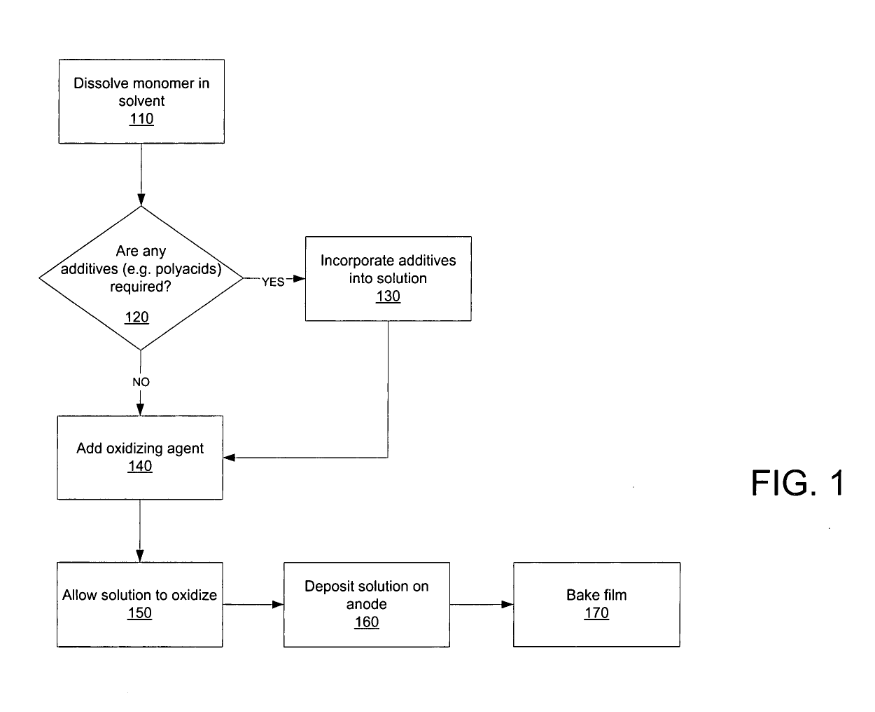

FIG. 1 illustrates a process flow for fabricating an ABL according to at least one embodiment of the invention. A monomer such as EDOT (3,4-ethylenedioxy-thiophene) is first dissolved in a solvent such as formic acid (block 110). In some embodiments, EDOT was dissolved in an 88% aqueous formic acid solution which was homogenous. Next, there may be additives which are required or desired (checked at block 120). These additives may include one or more of the following: polyacids, volatile acids, polyelectrolytes, electrolytes, non-volatile acids and salts. One example of a polyacid that can be used is PSS (poly(styrenesulfonic acid)) If so, then the additives are incorporated into the solution (block 130). The monomer solution, whether with additives or not is then allowed to oxidize (block 150) for a period of time. To aid the oxidization process, an oxidizing agent or agents would be added to the solution either prior or during oxidization (block 140). One exemplary oxidizing agent, used in some embodiments of the invention is hydrogen peroxide. In addition, the solution can be shaken at room temperature, either before or after the oxidizing agent, if any, is added.

Once the oxidization process is satisfactorily complete (for instance, after about 24 to 48 hours) the solution can be deposited onto the anode (of an OLED device) (block 160). There are many suitable deposition techniques, some selective and non-selective. Spin-coating is one common technique used in depositing the ABL layer. Once the solution is deposited, it begins to dry into a film. This film is baked in order to harden and stabilize it (block 170). In some embodiments of the invention, the baking temperature is anywhere between 100 and 200 degrees C.

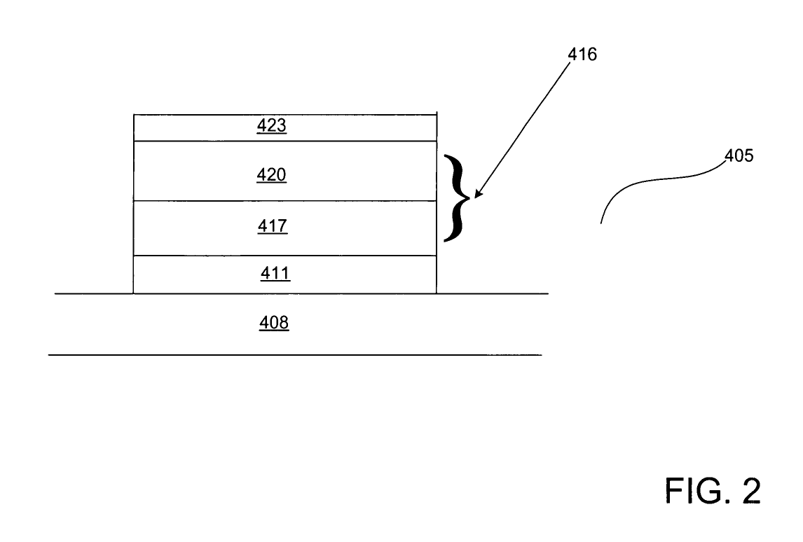

FIG. 2 shows a cross-sectional view of an embodiment of an OLED device 405 according to at least one embodiment of the invention. The OLED device 405 may represent one OLED pixel or sub-pixel of a larger OLED display. OLED device 405 is a passive-matrix device since it does not contain its own switching mechanism as with active matrix devices. As shown in FIG. 2, the OLED device 405 includes a first electrode 411 on a substrate 408. As used within the specification and the claims, the term “on” includes when layers are in physical contact or when layers are separated by one or more intervening layers. The first electrode 411 may be patterned for pixelated applications or unpatterned for backlight applications.

One or more organic materials is deposited into the aperture to form one or more organic layers of an organic stack 416. The organic stack 416 is on the first electrode 411. The organic stack 416 includes an anode buffer layer (“ABL”) 417 and light emitting polymer (LEP) layer 420. If the first electrode 411 is an anode, then the ABL 417 is on the first electrode 411. Alternatively, if the first electrode 411 is a cathode, then the LEP layer 420 is on the first electrode 411, and the ABL 417 is on the LEP layer 420. The OLED device 405 also includes a second electrode 423 on the organic stack 416. Other layers than that shown in FIG. 2 may also be added including barrier, charge transport, charge injection, planarizing, diffracting, and interface layers between or among any of the existing layers as desired. Some of these layers, in accordance with the invention, are described in greater detail below.

Substrate 408:

The substrate 408 can be any material that can support the organic and metallic layers on it. The substrate 408 can be transparent or opaque (e.g., the opaque substrate is used in top-emitting devices). By modifying or filtering the wavelength of light which can pass through the substrate 408, the color of light emitted by the device can be changed. The substrate 408 can be comprised of glass, quartz, silicon, plastic, or stainless steel; preferably, the substrate 408 is comprised of thin, flexible glass. The preferred thickness of the substrate 408 depends on the material used and on the application of the device. The substrate 408 can be in the form of a sheet or continuous film. The continuous film can be used, for example, for roll-to-roll manufacturing processes which are particularly suited for plastic, metal, and metallized plastic foils. A single substrate 408 is typically used to construct a larger OLED display containing many pixels such as OLED device 405 which are then arranged in some pattern.

First Electrode 411:

In one configuration, the first electrode 411 functions as an anode (the anode is a conductive layer which serves as a hole-injecting layer and which comprises a material with work function greater than about 4.5 eV). Typical anode materials include metals (such as platinum, gold, palladium, indium, and the like); metal oxides (such as lead oxide, tin oxide, ITO (Indium Tin Oxide), and the like); graphite; doped inorganic semiconductors (such as silicon, germanium, gallium arsenide, and the like); and doped conducting polymers (such as polyaniline, polypyrrole, polythiophene, and the like).

The first electrode 411 can be transparent, semi-transparent, or opaque to the wavelength of light generated within the device 405 depending on whether the device 405 is top-emitting or bottom-emitting. The thickness of the first electrode 411 can be from about 10 nm to about 1000 nm, preferably, from about 50 nm to about 200 nm, and more preferably, is about 100 nm. The first electrode layer 411 can typically be fabricated using any of the techniques known in the art for deposition of thin films, including, for example, vacuum evaporation, sputtering, electron beam deposition, or chemical vapor deposition.

In an alternative configuration, the first electrode layer 411 functions as a cathode (the cathode is a conductive layer which serves as an electron-injecting layer and which comprises a material with a low work function). The cathode, rather than the anode, is deposited on the substrate 408 in the case of, for example, a top-emitting OLED. Typical cathode materials are set forth below in the section for the “second electrode 423”.

ABL 417:

The ABL 417 typically has a much higher hole mobility than electron mobility and is used to effectively transport holes from the first electrode 411 to the LEP layer 420. The ABL 417 can be made of polymers or small molecule materials.

In accordance with the invention, the ABL 417 is formed from a solution made primarily of a monomer and a solvent such as formic acid. In some embodiments of the invention, a monomer known as EDOT (3,4-ethylene-dioxythiophene) is used. Other monomers that can be used in accordance with various embodiments of the invention include 3,4-dimethoxythiophene, 3-methoxythiophene, isothianaphthene and its derivatives, and pyrrole and its derivatives. Other additives such as polyacids, electrolyte, salts, acids and the like may be incorporated into the solution. For example, the additives may include one or more of the following: poly(styrene sulfonic acid) (PSS), poly(2-acrylamido-2-methyl-1-propanesulfonic acid), perfluorinated resins (such as NAFION™ from DuPont Chemical Corp.), 2-acrylamido-2-methyl-1-propanesulfonic acid, camphorsulfonic acid, dodecylbenzenesulfonic acid, poly(acrylic) acid and so on. Other additives may include one or more of the corresponding salts of the acids and polyacids mentioned above such as alkali metal salts, ammonium salts, tetraalkyl ammonium salts. Further, the formic acid may be mixed with other carboxylic acids such as acetic acid and acidic organic solvents such as meta-cresol. The solution is allowed to be oxidized by the assistance of an oxidizing agent such as hydrogen peroxide. Other oxidizing agents such as air, gaseous NOx (nitric oxides), iodine, bromine, chlorine, can be used. Organic peroxides such as t-Butyl peroxide can also be used. The oxidized solution can then be used as is in an organic electronic device, without the need of removing salts and other ionic byproducts. The solution can simply be filtered through a 1.0 μm filter prior deposition. It is then deposited (e.g. by spin coating) onto first electrode 411. The deposited solution dries into a film which is baked to harden.

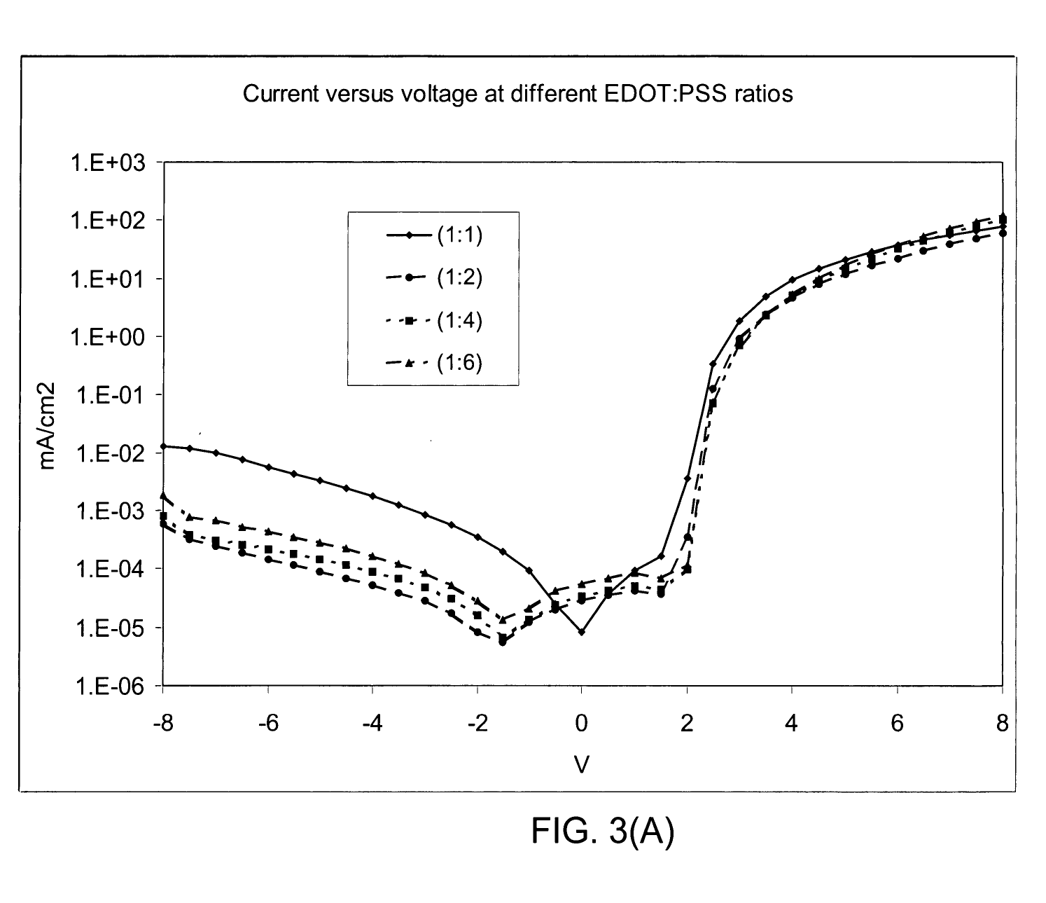

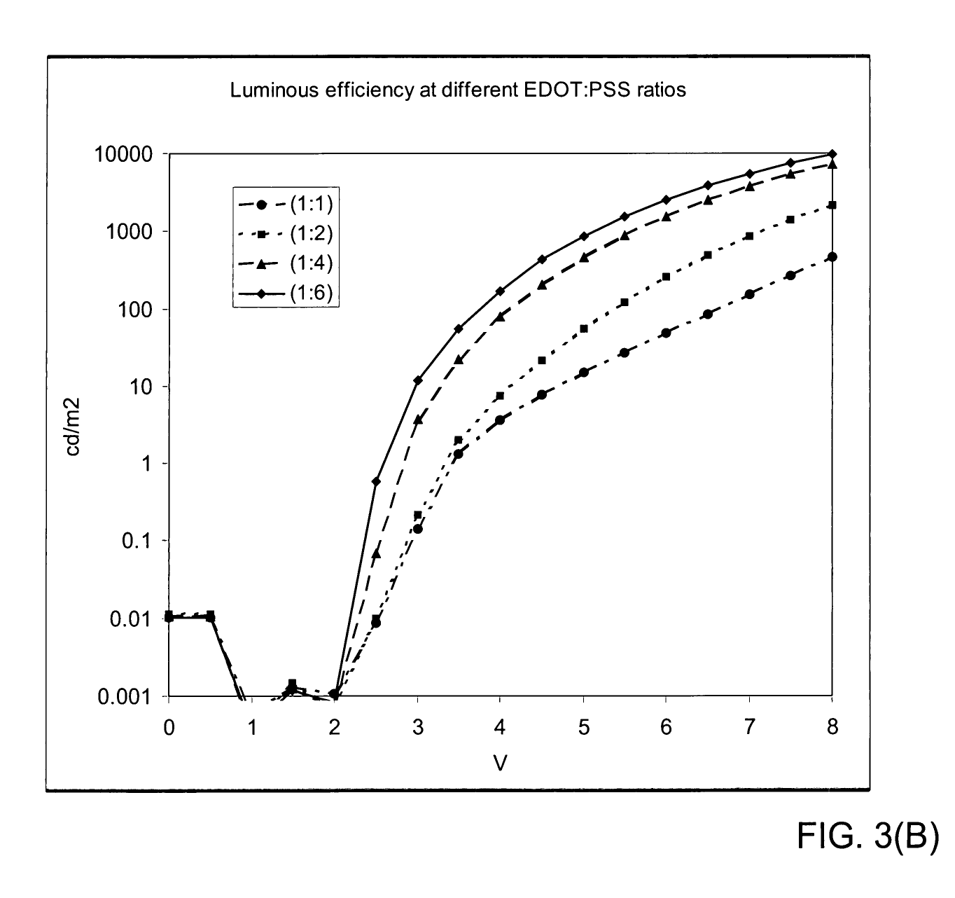

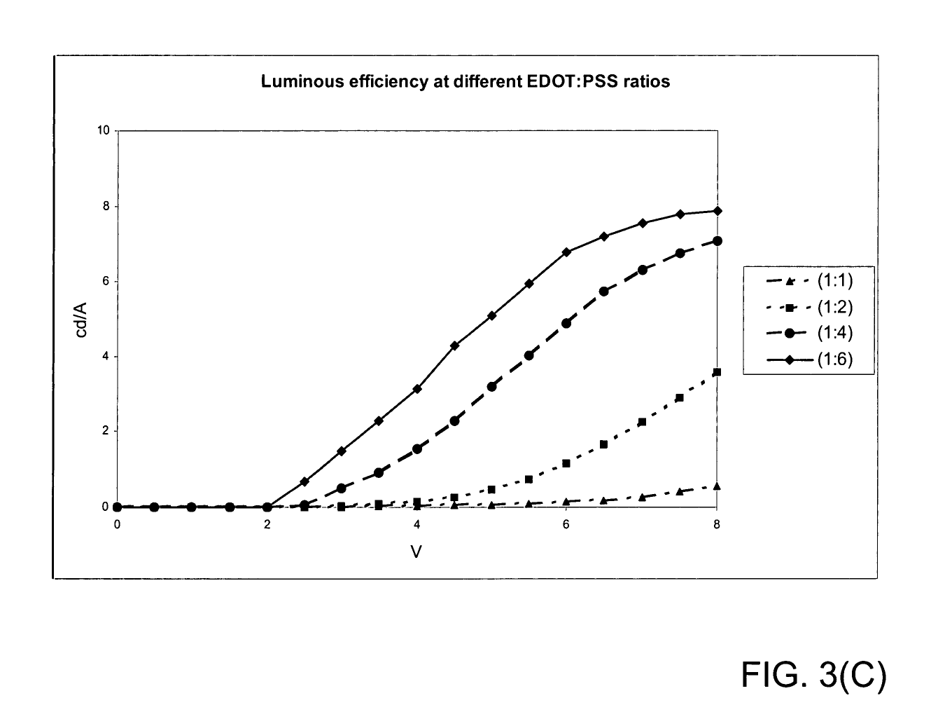

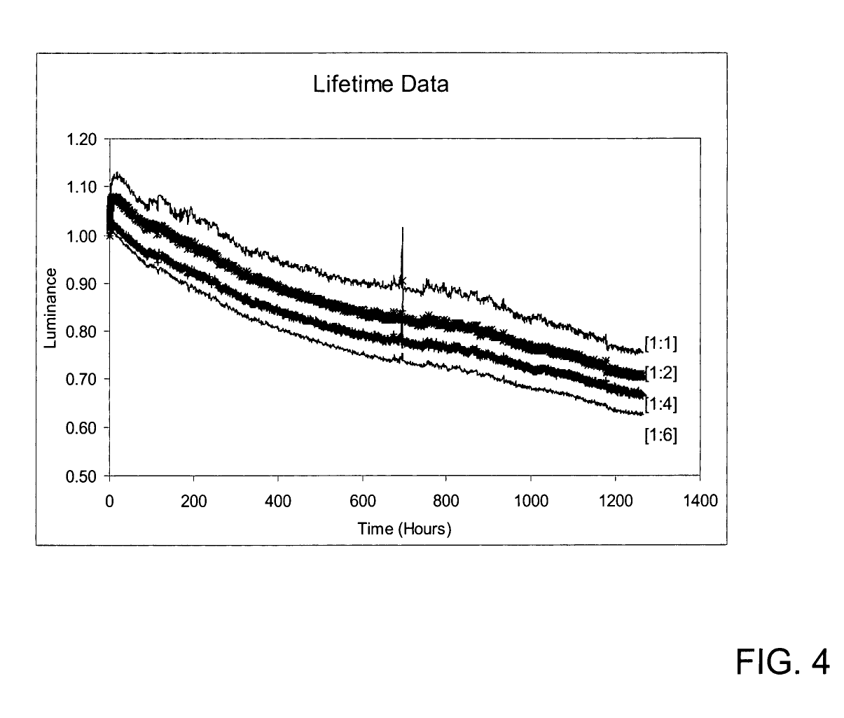

In one embodiment of the invention, EDOT monomer (3,4-ethylene-dioxythiophene) is dissolved in 88% aqueous formic acid to form a homogeneous solution. The EDOT monomer was found to be fully soluble in 88% formic acid. Then, 1 to 6 parts per weight (relative to EDOT) of polystyrene sulfonic acid (PSS) and 0.5 mole (relative to EDOT) of hydrogen peroxide are also added to the solution. In some embodiments of the invention, the solution was shaken for three days. These mixtures are bright dark blue and characterized by an absorption maximum at 680 nm, which is different from the absorption found in Baytron CH8000 and other PEDOT:PSS materials. This embodiment is modified by varying the amount of the PSS polyacid in each. The results are shown in FIGS. 3(A), 3(B), 3(C) and 4.

The ABL 417 can have a thickness from about 5 nm to about 1000 nm, and is conventionally used from about 50 to about 250 nm. In one or more embodiments of the invention, an ABL layer of about 100 nm is used. The ABL 417 can be deposited onto first electrode 411 using selective deposition techniques or nonselective deposition techniques. Examples of selective deposition techniques include, for example, ink jet printing, flex printing, and screen printing. Examples of nonselective deposition techniques include, for example, spin coating, dip coating, web coating, and spray coating. Once deposited the solution is baked to harden into a film. The hardened film becomes ABL 417.

LEP Layer 420:

For organic LEDs (OLEDs), the LEP layer 420 contains at least one organic material that emits light. These organic light emitting materials generally fall into two categories. The first category of OLEDs, referred to as polymeric light emitting diodes, or PLEDs, utilize polymers as part of LEP layer 420. The polymers may be organic or organo-metallic in nature. As used herein, the term organic also includes organo-metallic materials. Preferably, these polymers are dissolved in an organic solvent, such as toluene or xylene, and spun (spin-coated) onto the device, although other deposition methods are possible. Devices utilizing polymeric active electronic materials in LEP layer 420 are especially preferred. Optionally, LEP layer 420 may include a light responsive material that changes its electrical properties in response to the absorption of light. Light responsive materials are often used in detectors and solar panels that convert light energy to electrical energy.

The light emitting organic polymers in the LEP layer 420 can be, for example, EL polymers having a conjugated repeating unit, in particular EL polymers in which neighboring repeating units are bonded in a conjugated manner, such as polythiophenes, polyphenylenes, polythiophenevinylenes, or poly-p-phenylenevinylenes or their families, copolymers, derivatives, or mixtures thereof. More specifically, the organic polymers can be, for example: polyfluorenes; poly-p-phenylenevinylenes that emit white, red, blue, yellow, or green light and are 2-, or 2,5-substituted poly-p-pheneylenevinylenes; polyspiro polymers. Preferred organic emissive polymers include LUMATION Light Emitting Polymers (“LEPs”) that emit green, red, blue, or white light or their families, copolymers, derivatives, or mixtures thereof; the LUMATION LEPs are available from The Dow Chemical Company, Midland, Mich. Other polymers include polyspirofluorene-like polymers available from Covion Organic Semiconductors GmbH, Frankfurt, Germany.

In addition to polymers, smaller organic molecules that emit by fluorescence or by phosphorescence can serve as a light emitting material residing in LEP layer 420. Unlike polymeric materials that are applied as solutions or suspensions, small-molecule light emitting materials can also be deposited through evaporative, sublimation, or organic vapor phase deposition methods. Combinations of PLED materials and smaller organic molecules can also serve as active electronic layer. For example, a PLED may be chemically derivatized with a small organic molecule or simply mixed with a small organic molecule to form LEP layer 420.

In addition to active electronic materials that emit light, LEP layer 420 can include a material capable of charge transport. Charge transport materials include polymers or small molecules that can transport charge carriers. For example, organic materials such as polythiophene, derivatized polythiophene, oligomeric polythiophene, derivatized oligomeric polythiophene, pentacene, compositions including C60, and compositions including derivatized C60 may be used. LEP layer 420 may also include semiconductors, such as silicon or gallium arsenide. The LEP layer 420 typically has a thickness of greater than 80 nm and preferably, between 40 and 125 nm. For instance, in one embodiment of the invention, LEP layer 420 is a Green polyfluorene-based LUMATION™ LEP of about 100 nm.

All of the organic layers such as ABL 417 and LEP layer 420 can be ink-jet printed by depositing an organic solution or by spin-coating, or other deposition techniques. This organic solution may be any “fluid” or deformable mass capable of flowing under pressure and may include solutions, inks, pastes, emulsions, dispersions and so on. The liquid may also contain or be supplemented by further substances which affect the viscosity, contact angle, thickening, affinity, drying, dilution and so on of the deposited drops. Further, each of the layers 417 and 420 may be cross-linked or otherwise physically or chemically hardened as desired for stability and maintenance of certain surface properties desirable for deposition of subsequent layers.

Second Electrode (423)

In one embodiment, second electrode 423 functions as a cathode when an electric potential is applied across the first electrode 411 and second electrode 423. In this embodiment, when an electric potential is applied across the first electrode 411, which serves as the anode, and second electrode 423, which serves as the cathode, photons are released from active electronic layer 420 that pass through first electrode 411 and substrate 408.

While many materials, which can function as a cathode, are known to those of skill in the art, most preferably a composition that includes aluminum, indium, silver, gold, magnesium, calcium, and barium, or combinations thereof, or alloys thereof, is utilized. Aluminum, aluminum alloys, and combinations of magnesium and silver or their alloys can also be utilized.

Preferably, the thickness of second electrode 423 is from about 10 to about 1000 nanometers (nm), more preferably from about 50 to about 500 nm, and most preferably from about 100 to about 300 nm. While many methods are known to those of ordinary skill in the art by which the first electrode material may be deposited, vacuum deposition methods, such as physical vapor deposition (PVD) are preferred. Other layers (not shown) such as a barrier layer and getter layer may also be used to protect the electronic device. Such layers are well-known in the art and are not specifically discussed herein.

FIG. 3(A) illustrates current-voltage curves for various embodiments of the invention. There were four devices tested with the following characteristics. Each device used as materials for the ABL EDOT monomer in 88% formic acid with hydrogen peroxide. To this solution, each device used varying amounts of PSS. The first device had an EDOT to PSS weight ratio of 1:1, the second a ratio of 1:2, the third a ratio of 1:4 and the fourth a ratio of 1:6. The ABL was fabricated to have a thickness of about 100 nm in each device and each device used the green LUMATION™ LEP with a thickness of 100 nm. The substrates were glass (0.7 mm thickness) coated with an anode of ITO (indium tin oxide) (100 to 120 nm). The cathode was formed by evaporating around 3 nm of barium followed by evaporating around 200 nm of aluminum. The devices were then encapsulated with a glass lid containing a getter and sealed with a UV-curable glue.

The plot of current density (milliamperes/centimeter²) versus voltage shows that all devices had roughly similar characteristics. Notably, there is a current density of a reverse current of less than 10⁻³ mA/cm² at −8 volts of applied potential. FIG. 3(B) and FIG. 3(C) illustrates luminous efficiency for the same four devices as FIG. 3(A). The luminous efficiency as expressed in terms of brightness (candela/meter²) versus voltage (FIG. 3(A)) and as expressed in terms of luminous efficiency (candela/ampere) versus voltage shows that devices with a higher PSS content relative to the EDOT monomer show better efficiency.

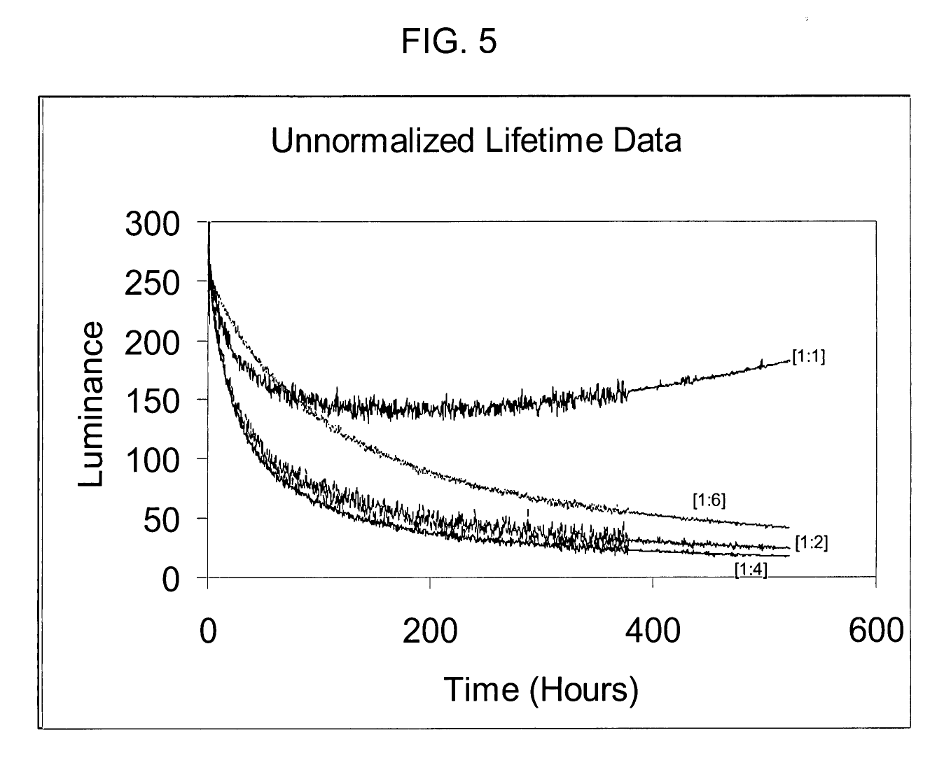

FIG. 4 illustrates normalized lifetime data for each of the four above-mentioned devices when driven under multiplexed (MUX) conditions at a MUX rate of 64. It can be seen that the MUX lifetime of the devices made with compositions having a low PSS content is better when compared to the same devices made with compositions having a higher PSS content. FIG. 5 illustrates un-normalized lifetime data for each of the four above-mentioned devices when driven under DC conditions. Unexpectedly, the devices made with an anode buffer layer having a EDOT:PSS ratio of 1 were found to have a very peculiar DC lifetime behavior. The luminance actually increased and trended upward after an initial decay to about 200 hours. The mechanism whereby the lifetime are improved by decreasing the PEDOT:PSS ratio may possibly involve the amount of acidic species in the anode buffer material. Thus, the amount of acid additives (such as PSS) will affect the lifetime performance, and can be tuned as desired.

Furthermore, the resistivity of ABL films made from these compositions is very high (on the order of 2 MOhm-cm (MegaOhm-centimeter)) even when the ratio of EDOT:PSS is around 1:6 and lower. This resistivity range is quite suitable for passive matrix displays. This is in sharp contrast with ABL films made from commercial products such as Baytron AI4083 which has a PEDOT:PSS ratio of 1:6 but whose resistivity is only 1 kOhm-cm, too low for passive matrix applications. To compensate, manufacturers are adding more polyacid (PSS) to end up with a ratio of 1:20 (as in Baytron CH8000) so that the resistivity is raised to 100 kOhm.cm

While the embodiments of the invention are illustrated in which it is primarily incorporated within an OLED display, almost any type of electronic device that uses dried film layers may be potential applications for these embodiments. In particular, present invention may also be utilized in a solar cell, a transistor, a phototransistor, a laser, a photo-detector, or an opto-coupler. It can also be used in biological applications such as bio-sensors or chemical applications such as applications in combinatorial synthesis etc. The OLED display described earlier can be used within displays in applications such as, for example, computer displays, information displays in vehicles, television monitors, telephones, printers, and illuminated signs.

What is claimed is:

1. An organic film, comprising:
a solution containing a monomer dissolved in a solvent; and
an oxidizing agent added to said solution, said solution allowed to oxidize without the presence of ionic byproducts thereby, said oxidized solution deposited and allowed to dry to form said film.

2. An organic film according to claim 1 further wherein said solution incorporates as additives at least one of: acids, polyacids, and salts.

3. An organic film according to claim 2 wherein said polyacids include at least one of: poly(sterene sulfonic acid), poly(2-acrylamido-2-methyl-1-propanesulfonic acid), poly(acrylic acid), a perfluorinated resin, and salts of said polyacids.

4. An organic film according to claim 2 wherein said acids include at least one of: camphorsulfonic acid, dodecylbenzenesulfonic acid, and 2-acrylamido-2-methyl-1-propanesulfonic acid, and their salts.

5. An organic film according to claim 1 wherein said oxidizing agent includes at least one of: hydrogen peroxide, hydrogen peroxide adducts, t-butyl peroxide, organic peroxides, and nitric oxide.

6. An organic film according to claim 1 wherein said solution additionally includes at least one of: acidic organic solvents and carboxylic acids.

7. An organic film according to claim 6 wherein acidic organic solvents include at least one of ortho-cresol, meta-cresol, para-cresol and nitromethane.

8. An organic film according to claim 1 wherein said solvent is 88% aqueous formic acid.

9. An organic film according to claim 1 wherein said monomer includes at least one of 3,4-ethylenedioxy-thiophene, 3,4-dimethoxythiophene, 3-methoxythiophene, isothianaphthene and its derivatives, and pyrrole and its derivatives.

10. An organic film according to claim 1 wherein said film is incorporated into an organic light emitting diode device as an anode buffer layer.

11. An organic film according to claim 1, with a lateral resistivity greater than 1 MegaOhm-centimeter.

12. An organic film according to claim 1 wherein said amount of added oxidizing agent is less than 0.5 mole equivalent relative to the monomer.

13. An organic film according to claim 12 wherein said oxidizing agent is hydrogen peroxide.

14. An organic light emitting device, comprising:
an anode;
an anode buffer layer disposed upon said anode, said anode buffer layer fabricated by depositing a solution containing a monomer dissolved in a solvent which is allowed to oxidize without the presence of ionic byproducts prior to deposition; and
a light emitting layer disposed on said anode buffer layer, said light emitting layer capable of emitting light upon electron hole recombination therein.

15. An organic light emitting device according to claim 14 further comprising:
a cathode disposed on said light emitting layer.

16. An organic light emitting device according to claim 14 further comprising:
a substrate, said anode disposed upon said substrate.

17. An organic light emitting device according to claim 14 wherein said solvent is 88% aqueous formic acid.

18. An organic light emitting device according to claim 17 wherein said monomer is 3,4-ethylenedioxy-thiophene.

19. An organic light emitting device according to claim 18 wherein said oxidizing agent is hydrogen peroxide.

20. An organic light emitting device according to claim 19 wherein said solution further contains poly(styrene sulfonic acid) (PSS).

21. An organic light emitting device according to claim 20 wherein the ratio of EDOT to PSS ranges between 1:1 and 1:6.

22. An organic light emitting device according to claim 14 wherein said light emitting layer is a conjugated polymer.

23. An organic light emitting device according to claim 14 further wherein said solution incorporates as additives at least one of: acids, polyacids, and salts.

24. An organic light emitting device according to claim 23 wherein said polyacids include at least one of: poly(styrene sulfonic acid), poly(2-acrylamido-2-methyl-1-propanesulfonic acid), poly(acrylic acid) and a perfluorinated resin.

25. An organic light emitting device according to claim 23 wherein said acids include at least one of: camphorsulfonic acid, dodecylbenzenesulfonic acid, and 2-acrylamido-2-methyl-1-propanesulfonic acid.

26. An organic light emitting device according to claim 23 wherein said oxidizing agent includes at least one of: hydrogen peroxide, t-butyl peroxide, and nitrous oxide.

27. An organic light emitting device according to claim 14 wherein said solution additionally includes at least one of: acidic organic solvents and carboxylic acids.

28. An organic light emitting device according to claim 27 wherein acidic organic solvents include meta-cresol.

29. An organic light emitting device according to claim 14 with a reverse current of less than 10⁻³ mA/cm² at −8 volts of applied potential.

30. A method of fabricating an anode buffer layer for an organic electronic device, said method comprising:
forming a solution of a monomer and a solvent containing formic acid;
adding an oxidizing agent to said solution;
allowing said solution to oxidize, said oxidizing agent disallowing the presence of ionic byproducts during oxidation; and
depositing said solution onto a surface in said organic electronic device.

31. A method according to claim 30 further comprising:
shaking said solution after said oxidizing agent is added.

32. A method according to claim 30 further comprising:
baking said deposited solution;

33. A method according to claim 32 wherein the temperature of baking is between 100 C. and 200 C.

34. A method according to claim 30 further comprising:
prior to oxidizing, adding to said solution at least one of: acids, polyacids, electrolytes and salts.

35. A method according to claim 34 wherein said polyacids include at least one of: poly(sterene sulfonic acid), poly(2-acrylamido-2-methyl-1-propanesulfonic acid), poly(acrylic acid) and a perfluorinated resin.

36. A method according to claim 35 wherein said acids include at least one of: camphorsulfonic acid, dodecylbenzenesulfonic acid, and 2-acrylamido-2-methyl-1-propanesulfonic acid.

37. A method according to claim 30 wherein said oxidizing agent includes at least one of: hydrogen peroxide, t-butyl peroxide, and nitrous oxide.

38. An organic light emitting device according to claim 30 further comprising: adding to said solvent at least one of acidic organic solvents and carboxylic acids.

39. An organic light emitting device according to claim 38 wherein acidic organic solvents include meta-cresol.

40. A method according to claim 30 wherein said organic electronic device is an organic light emitting diode (OLED) display.

41. A method according to claim 40 wherein said surface is an anode.

42. A method according to claim 41 wherein said solution after deposition dries into a film, said film being an anode buffer layer.

43. An organic light emitting device according to claim 14 wherein said monomer includes at least one of 3,4-ethylenedioxy-thiophene, 3-methoxythiophene, isothianaphthene and its derivatives, and pyrrole and its derivatives.

44. A method according to claim 30 wherein said monomer includes at least one of 3,4-ethylenedioxy-thiophene, 3-methoxythiophene, isothianaphthene and its derivatives, and pyrrole and its derivatives.
